(19) United States
(12) Patent Application Publication
(10) Pub. No.: US 2018/0261751 A1
(43) Pub. Date: Sep. 13, 2018

(54) METHOD FOR PRODUCING A THERMOELECTRIC MODULE

(71) Applicant: Mahle International GmbH, Stuttgart (DE)

(72) Inventor: Hans-Heinrich Angermann, Stuttgart (DE)

(21) Appl. No.: 15/911,053

(22) Filed: Mar. 2, 2018

(30) Foreign Application Priority Data
Mar. 3, 2017 (DE) 102017203493.9

(51) Int. Cl. H01L 35/34; H01L 35/32

(52) U.S. Cl. CPC H01L 35/34; H01L 35/32

(57) ABSTRACT

A method for producing a thermoelectric module may include arranging a plurality of thermoelectric elements between a hot-side substrate and a cold-side substrate such that the plurality of thermoelectric elements are at a distance from one another, and electrically connecting the plurality of thermoelectric elements to one another by a plurality of conductor bridges. The method may also include providing a multi-layer reactive joining mechanism between at least one conductor bridge of the plurality of connector bridges and at least one of the hot-side substrate and the cold-side substrate. The method may further include activating an exothermic chemical reaction in the multi-layer reactive joining mechanism to release energy and form a substance-to-substance bond that joins the at least one conductor bridge and the at least one of the hot-side substrate and the cold-side substrate. The method may further include the multi-layer reactive joining mechanism forming an electrically insulating insulating layer.

### CROSS-REFERENCE TO RELATED APPLICATIONS

This application claims priority to German Patent Application No. DE 10 2017 203 493.9, filed on Mar. 3, 2017, the contents of which are hereby incorporated by reference in its entirety.

### TECHNICAL FIELD

The present invention relates to a method for producing a thermoelectric module as well as a thermoelectric module, which is preferably produced by means of this method.

### BACKGROUND

Thermoelectric elements consist of thermoelectric semiconductor materials, which convert a temperature difference into a potential difference, thus into an electrical voltage, and vice versa. A heat flow can be converted into an electrical current and vice versa in this way. The thermoelectric modules are based on the Peltier effect, when they connect electrical energy into heat, and on the Seebeck effect, when they convert heat into electrical energy. Inside a thermoelectric module, p-doped and n-doped thermoelectric elements are connected to one another by means of electrical conductor bridges, typically made of a metal. A plurality of such thermoelectric modules is usually interconnected to form a thermoelectric generator, which, depending on the power supply, can be used to cool or to heat, or which can generate an electrical current from a temperature difference in connection with a corresponding heat flow.

For example, such thermoelectric modules or thermoelectric generators, respectively, can be used in internal combustion engines, in particular in motor vehicles, to recover waste heat, for example to convert waste heat contained in the exhaust gas into electrical energy. The temperatures, which vary within a large temperature range, in combination with the requirement that a heat transfer, which is as efficient as possible is desired inside the thermoelectric module between the thermoelectric elements and the substrates, while an electrical insulation needs to be present at the same time at this location, is problematic in such applications. On principle, materials, which have an excellent thermal conductivity, have an inferior electrical insulation. On principle, materials, which have an excellent thermal insulation, have an inferior electrical conductivity.

A production method for a thermoelectric module is known from WO 2012/120060 A2, in which two metallic cover plates, which are coated with a thin ceramic layer by means of thermal spraying, for the electrical simulation against the thermoelectric elements, are provided for embodying the hot side and the cold side of the module.

In conventional production methods for a thermoelectric module, it thereby turns out to be disadvantageous that the metallic cover plates need to be embodied to be relatively thick in order to keep mechanical tensions low or to avoid them completely when cooling down the insulating layer. In addition, it turns out to be relatively extensive from a technical aspect to apply the electrical conductor bridges, which connect the thermoelectric elements to one another, onto such an electrical insulating layer. In particular the risk of an electrical short-circuit between the conductor bridges and the metallic cover plates is significant.

### SUMMARY

The present invention deals with the problem of specifying an improved production method, which can in particular be carried out in a simple way and which is thus cost-efficient, for a thermoelectric module of the above-described type.

According to the invention, this problem is solved by means of the subject matter of the independent claim(s). Advantageous embodiments are the subject matter of the dependent claim(s).

It is thus the basic idea of the invention to use a suitable multi-layer, reactive joining means for the production of a thermoelectric module. According to the invention, the reactive joining means serves the purpose of establishing a substance-to-substance bond between the electrical conductor bridges and the two substrates, which form the hot side or cold side, respectively, of the module—hereinafter identified as “hot-side or cold-side substrate”, respectively. This occurs by means of an external activation of a chemical reaction in the reactive joining means, so that the energy released in response to the reaction can be used to form said substance-to-substance bond.

A selection of the reactive joining means in such a way that it forms an electrically insulating insulating layer between the conductor bridges and the hot-side or cold-side substrate, respectively, after the exothermic reaction, is significant for the invention. The electrical insulating layer thus insulates the respective substrate against the electrical conductor bridges. On the one hand, the joining means thus serves to create a permanent tight connection by means of substance-to-substance bond between the electrical conductor bridges and the two substrates. On the other hand, the joining means also serves as electrical insulation between the conductor bridges and the two metallic substrates forming the hot or cold side, respectively, after having been joined. On the one hand, the provision of a separate electrical insulating layer, for example in the form of a dielectric film or of another suitable dielectric, becomes superfluous in this way. On the other hand, it is possible to form the two substrates in a metallic manner as proposed, so that they have a very high thermal conductivity.

As a result, the heat transfer characteristics of the thermoelectric module can thus be improved significantly. At the same time, the method according to the invention can be carried out relatively easily from a technical aspect, because, in addition to the two joining partners, thus the conductor bridges and the substrates, only the joining means, which is significant for the invention, needs to be provided. As a result, a thermoelectric module, which is set up with a very simple construction and which can thus be produced in a cost-efficient manner, can thus be produced by using the method according to the invention, which is presented here, and which has excellent heat transfer characteristics and thus also a high efficiency.

In the case of the method according to the invention for producing a thermoelectric module, a plurality of thermoelectric elements, which are arranged at a distance to one another and which are connected to one another by means of electrical conductor bridge, are provided in a step a). The thermoelectric elements including the conductor bridges are arranged between a hot-side metallic substrate and a cold-side metallic substrate according to step a). In a step b), a multi-layer reactive joining means is provided or arranged, respectively, between at least one conductor bridge, preferably between a plurality of conductor bridges, and/or the hot-side or cold-side substrate. In a step c), an exothermic chemical reaction is activated in this joining means, and the energy released thereby is used to connect the at least one conductor bridge to the hot-side or cold-side substrate, respectively, by means of a substance-to-substance bond. According to the invention, the reactive joining means provided in step b) is thereby selected in such a way that it forms an electrically insulating insulating layer between the conductor bridges and the hot-side or cold-side substrate, respectively, after the exothermic reaction according to step c).

The electrically insulating insulating layer preferably at least partially includes components of the multi-layer joining means.

According to a preferred embodiment, the activation in step c) occurs by means of a, preferably local, energization on the reactive joining means, preferably by means of electrical, optical or thermal energization or by means of a combination of at least two of the mentioned types of pressurization.

In an advantageous further development, the substance-to-substance bond generated in step c) is formed by means of the reaction product, which is generated from the joining means by means of the exothermic chemical reaction. This significantly simplifies the performance of the production method according to the invention as compared to conventional methods.

Advantageously, an electrical energization can take place by supplying an electrical ignition pulse to the reactive joining means. In a likewise advantageous manner, the optical energization can take place by directing a laser beam to the reactive joining means. In the case of at thermal energization, the latter can take place in a particularly advantageous manner by supplying a fire or spark into the reactive joining means. All of the above-mentioned variations can be realized in a technically simple manner and thus have an advantageous effect on the production costs for the thermoelectric module.

In an advantageous further development, the joining means in each case comprises at least one, preferably in each case a plurality of first and second individual layers, which are arranged alternately on top of one another. In the alternative, the joining means can also consist of a plurality of first and second individual layers, which are arranged alternately on top of one another. In both variations of this further development, the first individual layers are embodied as carbide or boride or nitride or oxide and include at least one of the elements copper (Cu), iron (Fe) or nickel (Ni). In this further development the second individual layers include at least one of the elements chromium (Cr), titanium (Ti), aluminum (Al), Si (silicon).

Advantageously, the joining means can be applied to the at least one conductor bridge and/or the hot-side or cold-side substrate, respectively, in step b).

In an advantageous further development, the joining means is embodied as multi-layer film, which is arranged, preferably in a sandwich-like manner, between the at least one conductor bridge, and the hot-side or cold-side substrate, respectively, in step b).

The entire joining process can be simplified further in an advantageous further development, according to which a soldering agent, which preferably contains tin (S) or consists of tin (Sn), is applied to the film prior to joining the at least one conductor bridge and the cold-side substrate. A particularly homogenous embodiment of the substance-to-substance bond is supported by using such a soldering agent.

Prior to the joining according to step c), the joining means provided in step b), particularly preferably the multi-layer film, is embodied in such a way in particular with regard to its layer thickness and its material composition that it has a specific electrical resistance p of more than 5*10⁻³ Ohm*m, preferably of more than 5*10⁻² Ohm*m, after the joining process according to step c). It is ensured in this way that the reaction product resulting from the joining means after the external reaction, has the desired, electrically insulating property. The provision of a separate electrical insulation can thus be forgone as well.

In a further preferred embodiment, the cold-side substrate can include copper (Cu) and/or aluminum (Al) or can consist of copper (Cu) or aluminum (Al). In the alternative or in addition, the hot-side substrate can include a ferritic iron (Fe) base material or can consist of such a ferritic iron (Fe) base material in this embodiment.

At least one of the two substrates provided in step a) is preferably embodied as substrate plate comprising a plate thickness of maximally 1.0 mm, preferably of maximally 0.5 mm, highly preferably of maximally 0.3 mm Particularly preferably, the hot-side substrate as well as the cold-side substrate are embodied in this way.

The invention further relates to a thermoelectric module, in particular a thermoelectric generator or a thermoelectric heat pump, which was produced by means of the above-described method according to the invention. The above-described advantages of the method can thus also be transferred to the thermoelectric module according to the invention.

The invention also relates to a thermoelectric module, in particular a thermoelectric generator or a thermoelectric heat pump. The module comprises a plurality of thermoelectric elements, which are arranged spaced apart from one another between a hot side of the module and a cold side of the module. The module comprises a plurality of conductor bridges for electrically interconnecting the thermoelectric elements. The module also comprises a hot-side substrate, which forms the hot side, and a cold-side substrate, which forms the cold side. The conductor bridges are joined to the hot-side or to the cold-side substrate, respectively, by means of a substance-to-substance bond by means of a joining means, in which an exothermic reaction was activated. After the activation of the exothermic reaction, the joining means forms an electrical insulating layer, which electrically insulates the respective substrate against the electrical conductor bridges. The thermoelectric module according to the invention can preferably be produced by means of the above-described method according to the invention. The above-described advantages of the method can be transferred to the thermoelectric module in this case.

The thermoelectric module can have a housing, which includes a hermetically sealed interior, in which the thermoelectric elements are arranged. The thermoelectric elements in the interior are thus protected against harmful environmental influences, for example against contaminations and moisture. The interior can be evacuated or can be filled with a protective gas. In the alternative, it is possible, on principle, that the hot-side substrate is part of a wall of the heating channel for guiding a heating fluid, wherein provision can be made additionally or in the alternative for the cold-side substrate to be a part of a wall of a cooling channel for guiding a cooling fluid. By means the integration of the respective substrate into the wall of such a channel, the heat transfer between the substrate and the respective fluid is improved, because a direct contacting of the respective fluid with the respective substrate occurs.

The respective thermoelectric module is advantageously configured as flat, plate-shaped body. The substrates are thus preferably also plate-shaped bodies, which in each case extend in a plane. In the alternative, it is possible on principle to embody such a thermoelectric module in a cylindrical or cylinder segment-shaped manner, so that the substrates have corresponding curved shapes.

Further important features and advantages of the invention follow from the subclaims, from the drawings, and from the corresponding figure description by means of the drawings.

It goes without saying that the above-mentioned features and the features, which will be described below, cannot only be used in the respective specified combination, but also in other combinations or alone, without leaving the scope of the present invention.

Preferred exemplary embodiments of the invention are illustrated in the drawings and will be described in more detail in the description below.

### BRIEF DESCRIPTION OF THE DRAWINGS

In each case schematically,

FIGS. 1 and 2 show representations illustrating the production method according to the invention;

FIG. 3 shows the thermoelectric module of FIG. 1 after an at least partial exothermic chemical reaction is triggered in a multi-layer joining mechanism.

### DETAILED DESCRIPTION

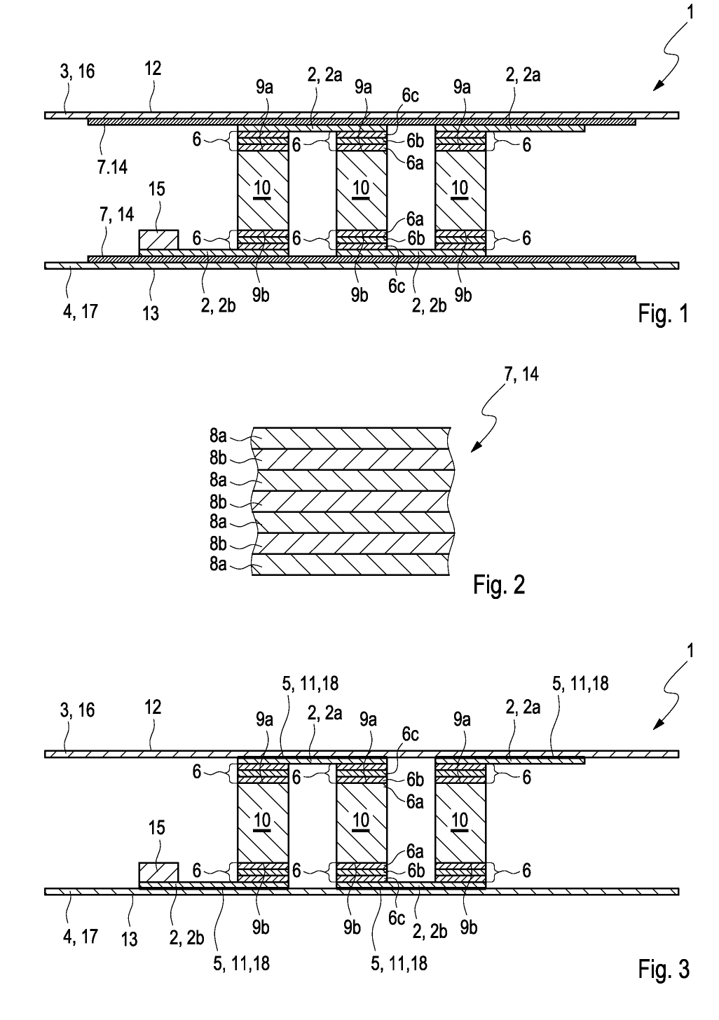

According to FIG. 1, a plurality of thermoelectric elements 10, which are arranged at a distance to one another and which are electrically connected to one another by means of conductor bridges 2, are provided in a step a) between a hot-side substrate 3 of a metallic material and a cold-side substrate 4 of a metallic material for producing a thermoelectric module 1 according to the invention. The metallic materials used for the two substrates 3, 4 are preferably different.

Exactly three such thermoelectric elements 2 are shown in FIG. 1 in a purely exemplary manner. It is clear that such a module 1 can on principle have any number of such thermoelectric elements 2, which are preferably arranged at least two-dimensionally, thus not only along the drawing plane, but also perpendicular thereto. The hot-side substrate 3 can include a ferritic iron (Fe) base material or can consist of such a ferritic iron (Fe) base material. The cold-side metallic substrate 4 can include copper (Cu) as well as, in the alternative or additionally, aluminum (Al) or can consist of copper (Cu) or aluminum (Al). The hot-side as well as the cold-side substrate 3, 4, can in each case be embodied as substrate plate 16, 17 with a plate thickness of maximally 1.0 mm. A plate thickness of maximally 0.5 mm, particularly preferably of maximally 0.3 mm, is preferred.

The conductor bridges 2 serve to electrically interconnect the thermoelectric elements 10 as well as to connect electrical terminals 15, of which at least two are present for each module 1, but of which only one single connection 15 is illustrated in an exemplary manner in FIG. 1. On principle, the conductor bridges 2 can be made of any electrically and thermally conductive material.

Those conductor bridges 2, which face the hot-side substrate 3, are additionally identified with reference numeral 2a in the figures. Those conductor bridges 2, which face the cold-side substrate 4, are additionally identified with reference numeral 2b in the figures. An outer side of the hot-side substrate 3, which faces away from the thermoelectric elements 10, forms a hot side 12 of the thermoelectric module 1. An outer side of the cold-side substrate 4, which faces away from the thermoelectric elements 10, forms a cold side 13 of the thermoelectric module 1.

The outer sides 9a of the thermoelectric elements 10, which face the hot side 12, can be coated with an adapter layer 6, which comprises a plurality of individual layers. The individual layers of the adapter layer 6 can in particular serve to promote adhesion between the thermoelectric elements 10 and the conductor bridges 2. Analogously, the outer sides 9b of the thermoelectric elements 10, which face the cold side 13, can be coated with an adapter layer 6, which can also comprise a plurality of individual layers. In the example of the figures, the adapter layer 6 in each case has three individual layers 6a, 6b, 6c in a purely exemplary manner.

The conductor tracks 2a and 2b and the substrates 3 and 4 can be provided with an adapter layer to improve the adhesion of the joining means. It is preferable, however, when the reactive joining means develops so much heat that the substrates 3 and 4 are melted on the surface and an adhesion between substrate and joint is thus established.

In a step b), a multilayer joining means 7 is provided between the conductor bridges 2 comprising the adapter layers 6 and the two substrates 3, 4. In step b), the reactive joining means 7 can initially be applied onto the conductor bridges 2 comprising the adapter layers 6 or, in the alternative, onto the hot-side or cold-side substrate 3, 4, respectively.

FIG. 1 shows the thermoelectric module 1 after performing the method steps a) and b). The joining means 7 comprising the individual layers 8a, 8b can be formed by means of a multi-layer film 14.

In a third step c), an exothermic reaction is triggered in the reactive joining means 7. The conductor bridges 2, 2a, which face the hot-side substrate 3, are jointed to the hot-side substrate 3 through this by means of a substance-to-substance bond. The conductor bridges 2, 2b, which face the cold-side substrate 4, are likewise joined to the cold-side substrate 4 by means of a substance-to-substance bond. To form the substance-to-substance bond, the energy, which is released in response to the exothermic chemical reaction, is at least partially used.

The joining means 7 provided in step b) is now chosen in such a way that it forms an electrically insulating insulating layer 18 between the conductor bridges 2 and the hot-side or cold-side substrate 3, 4, respectively, after the exothermic reaction according to step c).

FIG. 3 shows the thermoelectric module 1 after performing the method steps a) to c). The joining of the conductor bridge 2a, 2b and of the hot-side or cold-side substrate 3, 4, respectively, occurs by activation of an exothermic chemical reaction in the multi-layer reactive joining means 7. Energy released in response to the exothermic reaction is thereby used to form the substance-to-substance bond 5 between the joining partners, thus between the conductor bridges 2, 2a, 2b and the hot-side or cold-side substrate 3, 4, respectively. The activation of the exothermic reaction can occur in step c) by means of local energization on the reactive joining means 7 by means of electrical, optical, chemical or thermal energization from the outside. The substance-to-substance bond 5 is thereby formed by means of the reaction product 11, which is generated from the joining means 7 by means of the exothermic chemical reaction, which is only suggested schematically in FIG. 3.

An electrical energization can occur by supplying an electrical ignition pulse to the reactive joining means 7. An optical energization can occur by supplying a laser beam into the reactive joining means 7. A thermal energization can occur by supplying a fire or a spark into the reactive joining means 7.

FIG. 2 shows a possible setup of the multi-layer joining means 7 prior to the activation of the exothermic reaction according to step c) in an exemplary manner. In the example of FIG. 3, the joining means 7 comprises a plurality of first and second individual layers 8a, 8b, which are arranged alternately on top of one another. The first individual layer 8a are embodied as carbide or boride or nitride or oxide and include at least one of the following elements: copper (Cu), iron (Fe) or nickel (Ni). The second individual layers 8b in each case include at least one of the following elements: chromium (Cr), titanium (Ti), aluminum (Al), Si (silicon).

Prior to the joining of the conductor bridges 2b to the cold-side substrate 4, a soldering agent (not illustrated in the figures), which preferably includes tin (s) or consists of tin (Sn), can be applied to the multi-layer joining means 7 in a further development of the method.

Prior to the joining according to step c), the multi-layer joining means 7 provided in step b) is selected in such a way, in particular with regard to its layer thickness and its material composition that it has a specific electrical resistance of more than 5*10⁻³ Ohm*m, preferably of more than 5*10⁻² Ohm*m, after the joining according to step c).

The thermoelectric module 1 can also have a housing, which is not illustrated in detail in the figures, which includes an interior, which is hermetically sealed to the outside. The thermoelectric elements 10 are arranged in this interior. Advantageously, two walls of the housing, which face away from one another or two walls, which are spaced apart from one another, respectively, of the housing are formed by the two substrates 3, 4. In the case of an alternative construction, the hot-side substrate 3 can form a part of a wall of a heating channel, in which a heating fluid is guided. In addition or in the alternative, the cold-side substrate 4 can form a part of a wall of a cooling channel, in which a coolant is guided. The thermoelectric modules 1 can be integrated into a heat exchanger particular easily through this.

1. A method for producing a thermoelectric module, comprising the following steps:
a) arranging a plurality of thermoelectric elements between a hot-side substrate of a first metallic material and a cold-side substrate of a second metallic material such that the plurality of thermoelectric elements are at a distance from one another, and electrically connecting the plurality of thermoelectric elements to one another via a plurality of conductor bridges;
b) providing a multi-layer reactive joining mechanism between at least one conductor bridge of the plurality of connector bridges and at least one of the hot-side substrate and the cold-side substrate;
c) activating an exothermic chemical reaction in the multi-layer reactive joining mechanism to release energy and form a substance-to-substance bond that, at least partially, joins the at least one conductor bridge and the at least one of the hot-side substrate and the cold-side substrate;
wherein after activating the exothermic chemical reaction the multi-layer reactive joining mechanism forms an electrically insulating insulating layer between the at least one conductor bridge and the at least one of the hot-side substrate and the cold-side substrate.

2. The method according to claim 1, wherein the multi-layer reactive joining mechanism includes a plurality of components, and after activating the exothermic reaction the electrically insulating insulating layer includes at least one of the plurality of components of the multi-layer reactive joining mechanism.

3. The method according to claim 1, wherein the activation of the exothermic chemical reaction in step c) is initiated by an energization of the multi-layer reactive joining mechanism.

4. The method according to claim 1, wherein the substance-to-substance bond in step c) is formed by a reaction product generated from the activation of the exothermic chemical reaction of the multi-layer reactive joining mechanism.

5. The method according to claim 16, wherein at least one of:
the electrical energization is initiated by supplying an electrical ignition pulse to the multi-layer reactive joining mechanism;
the optical energization is initiated by supplying a laser beam into the multi-layer reactive joining mechanism; and
the thermal energization is initiated by supplying a fire into the multi-layer reactive joining mechanism.

6. The method according to claim 1, wherein:
the multi-layer reactive joining mechanism includes at least one first individual layer and at least one second individual layer arranged on top of one another;
the first individual layer is one of a carbide, a boride, a nitride, and an oxide and includes at least one of copper, iron, and nickel; and
the second individual layer includes at least one of chromium, titanium, aluminum, and silicon.

7. The method according to claim 1, wherein step b) includes applying the multi-layer reactive joining mechanism means to at least one of i) the at least one conductor bridge and ii) the at least one of the hot-side substrate and the cold-side substrate.

8. The method according to claim 1, wherein the multi-layer reactive joining mechanism is a multi-layer film arranged in a sandwich-like manner between the at least one conductor bridge and the at least one of the hot-side substrate and the cold-side substrate.

9. The method according to claim 8, wherein:
activating an exothermic chemical reaction joins the at least one conductor bridge and the cold-side substrate; and
prior to activating the exothermic chemical reaction a soldering agent is applied to the multi-layer film.

10. The method according to claim 1, wherein after activating the exothermic chemical reaction according to step c), the multi-layer reactive joining mechanism has a specific electrical resistance of more than 5*10⁻³ Ohm*m.

11. The method according to claim 1, wherein at least one of:
the cold-side substrate includes at least one of copper and aluminum; and
the hot-side substrate includes a ferritic iron base material.

12. The method according to claim 1, wherein at least one of the hot-side substrate and the cold-side substrate is a substrate plate having a plate thickness of maximally 1.0 mm.

13. A thermoelectric module, produced according to a method comprising:
a) arranging a plurality of thermoelectric elements between a hot-side substrate of a first metallic material and a cold-side substrate of a second metallic material such that the plurality of thermoelectric elements are at a distance from one another, and electrically connecting the plurality of thermoelectric elements to one another by a plurality of conductor bridges;
b) providing a multi-layer reactive joining mechanism between at least one conductor bridge of the plurality of connector bridges and at least one of the hot-side substrate and the cold-side substrate;
c) activating an exothermic chemical reaction in the multi-layer reactive joining mechanism to release energy and form a substance-to-substance bond that, at least partially, joins the at least one conductor bridge and the at least one of the hot-side substrate and the cold-side substrate;
wherein after activating the exothermic chemical reaction the multi-layer reactive joining mechanism forms an electrically insulating insulating layer between the at least one conductor bridge and the at least one of the hot-side substrate and the cold-side substrate.

14. A thermoelectric module, comprising:
a plurality of thermoelectric elements arranged spaced apart from one another between a hot side of a module and a cold side of the module, the hot side formed of a hot-side substrate and the cold side formed of a cold-side substrate;
a plurality of conductor bridges electrically interconnecting the plurality of thermoelectric elements, the hot-side substrate, and the cold-side substrate;
the plurality of conductor bridges joined to at least one of the hot-side substrate and the cold-side substrate via a substance-to-substance bond formed from an exothermically reacted multi-layered reactive joining mechanism;
wherein the multi-layered reactive joining mechanism forms an insulating layer electrically insulating the hot-side substrate and the cold-side substrate against the plurality of conductor bridges.

15. The method according to claim 1, wherein the substance-to-substance bond completely joins the at least one conductor bridge and the at least one of the hot-side substrate and the cold-side substrate.

16. The method according to claim 3, wherein the energization of the multi-layer reactive joining mechanism includes at least one of electrical energization, optical energization, and thermal energization.

17. The method according to claim 1, wherein:
the multi-layer reactive joining mechanism includes a plurality of first individual layers and a plurality of second individual layers arranged alternatingly on top of one another;
the first individual layers are one of a carbide, a boride, a nitride, and an oxide and includes at least one of copper, iron, and nickel; and
the second individual layers including at least one of chromium, titanium, aluminum, and silicon.

18. The method according to claim 9, wherein the soldering agent includes tin.

19. The method according to claim 1, wherein after activating the exothermic chemical reaction according to step c), the multi-layer reactive joining mechanism has a specific electrical resistance of more than 5*10⁻² Ohm*m.

20. The method according to claim 1, wherein activating the exothermic chemical reaction includes energizing the multi-layer reactive joining mechanism to activate the exothermic reaction, and producing a reaction product that forms the substance-to-substance bond by activating the exothermic reaction.
